(19) United States
(12) Patent Application Publication
(10) Pub. No.: US 2016/0013053 A1
(43) Pub. Date: Jan. 14, 2016

(54) Method of Manufacturing Semiconductor Device, Substrate Processing Apparatus and Non-Transitory Computer-Readable Recording Medium

(71) Applicant: Hitachi Kokusai Electric Inc., Tokyo (JP)

(72) Inventors: Hiroshi ASHIHARA, Toyama (JP); Shin HIYAMA, Toyama (JP); Masahisa OKUNO, Toyama (JP); Yuichi WADA, Toyama (JP); Harunobu SAKUMA, Toyama (JP)

(21) Appl. No.: 14/862,980

(22) Filed: Sep. 23, 2015

Related U.S. Application Data
(63) Continuation of application No. PCT/JP2014/058300, filed on Mar. 25, 2014.

(30) Foreign Application Priority Data
Mar. 26, 2013 (JP) 2013-064147

(51) Int. Cl. H01L 21/02; C23C 14/54; C23C 14/24

(52) U.S. Cl. CPC H01L 21/02345; H01L 21/02222; H01L 21/02337; C23C 14/24; C23C 14/54

(57) ABSTRACT

By obtaining a high-quality film by improving the quality of an oxide film formed at a low temperature, manufacturing costs of a large-scale integrated circuit (LSI) may be decreased. A method of manufacturing a semiconductor device includes (a) accommodating a substrate having thereon a film containing a silazane bond in a process chamber; (b) generating a process gas by supplying a process liquid containing hydrogen peroxide to an evaporator and supplying the process gas to the substrate; and (c) supplying a microwave to the substrate after processing the substrate with the process gas.

### CROSS REFERENCE TO RELATED APPLICATIONS

This application is a continuation of International Application No. PCT/JP2014/058300, filed on Mar. 25, 2014, which claims priority under 35 U.S.C. §119(a)-(d) to Application No. JP 2013-064147 filed on Mar. 26, 2013, the entire contents of which are hereby incorporated by reference.

### FIELD OF THE INVENTION

The present invention relates to a method of manufacturing a semiconductor device, in which a substrate is processed using a gas, a substrate processing apparatus and a non-transitory computer-readable recording medium.

### BACKGROUND

As large-scale integrated circuits (hereinafter referred to as LSIs') are becoming finer, technical difficulties in processing techniques for controlling interference between transistor devices caused by a leakage current are becoming higher. Elements of an LSI are separated by forming a gap such as a groove or a hole between elements of a silicon (Si) substrate to be separated from each other, and depositing an insulating material in the gap. In most cases, an oxide film, e.g., a silicon oxide film, is used as an insulating material. The silicon oxide film is formed by oxidizing a silicon (Si) substrate or by chemical vapor deposition (CVD) or spin-on dielectric (SOD).

As LSIs have recently been developed to be finer, a technique of filling a fine structure, and particularly, a technique of filling an oxide into a structure having a gap, which is deep in a vertical direction or is narrow in a horizontal direction, by CVD is reaching the limit of its technical feasibility. For reasons such as this, there is a growing tendency to employ a filling method using an oxide having fluidity, that is, SOD. In SOD, an insulating coating material containing an inorganic or organic substance which is referred to as spin-on glass (SOG) is used. Although the insulating coating material was employed in a process of manufacturing an LSI before the advent of an oxide film formed by CVD, a processing dimension of a technique of processing the insulating coating material is not very fine at about of 0.35 μm to 1 μm. Thus, after the insulating coating material is applied, the insulating coating material is modified by heating it at about 400° C. in a nitrogen atmosphere. Recently, a minimum processing dimension of, for example, an LSI, a dynamic random access memory (DRAM), or a flash memory, is less than 50 nm in width. Thus, a growing number of device makers are using polysilazane instead of SOG.

Polysilazane is a material obtained, for example, through a catalytic reaction of either dichlorosilane or trichlorosilane and ammonia, and is used to form a thin film by applying polysilazane on a substrate using a spin coater. The thickness of the thin film is adjusted according to the molecular weight or viscosity of polysilazane or the number of rotations of the spin coater.

It is known that polysilazane contains, as impurities, nitrogen generated from ammonia while polysilazane is formed. Thus, in order to obtain a nitrogen-free oxide film having a dense structure, moisture should be added to polysilazane and polysilazane should be thermally processed after polysilazane is applied on a substrate. To add moisture to polysilazane, a method of generating moisture by causing oxygen and hydrogen to react with each other in a body of a thermal process furnace has been known. An oxide film having a dense structure may be obtained by adding the generated moisture into a polysilazane film and heating the polysilazane film. In this case, a maximum temperature at which the heating of the polysilazane film is performed may be about 1000° C. during shallow trench isolation (STI).

As polysilazane has been widely used in an LSI process, there is a growing need to decrease a heat load on a transistor. The heat load should be decreased to prevent excessive diffusion of impurities, such as boron, arsenic, phosphorus, etc., which are injected to operate a transistor, prevent agglomeration of a metal silicide for an electrode, prevent a change in the performance of a work function metal material for a gate, secure a long lifetime of a memory device even when a write/read operation is repeatedly performed thereon, etc. Thus, when moisture is effectively added in a moisture adding process, a heat load decreases in a heating process performed after the moisture adding process.

However, as a minimum processing dimension of a semiconductor device, e.g., an LSI, a dynamic random access memory (DRAM), or a flash memory, is becoming smaller than 50 nm in width, it is difficult to microfabricate components thereof, improve the manufacturing throughput thereof, or decrease a process temperature while maintaining the quality of the semiconductor device.

### SUMMARY

It is an objective of the present invention to provide a method of manufacturing a semiconductor device, which is capable of improving the manufacturing throughput of a semiconductor device while improving the manufacturing quality thereof, a substrate processing apparatus and a non-transitory computer-readable recording medium.

According to one aspect of the present invention, a method of manufacturing a semiconductor device includes (a) accommodating a substrate having thereon a film containing a silazane bond in a process chamber; (b) generating a process gas by supplying a process liquid containing hydrogen peroxide to an evaporator and supplying the process gas to the substrate; and (c) supplying a microwave to the substrate after processing the substrate with the process gas.

According to another aspect of the present invention, a substrate processing apparatus includes a process chamber configured to accommodate a substrate having thereon a film containing a silazane bond; an evaporation device including an evaporator configured to receive a process liquid containing hydrogen peroxide; a microwave supply unit configured to supply a microwave to the substrate; and a control unit configured to control the evaporation device and the microwave supply unit to generate a process gas from the process liquid supplied to the evaporator and supply the microwave to the substrate after the process gas is supplied to the substrate.

According to another aspect of the present invention, there is provided a non-transitory computer-readable recording medium storing a program for causing a computer to control a substrate processing apparatus to perform (a) accommodating a substrate having thereon a film containing a silazane bond in a process chamber; (b) generating a process gas by supplying a process liquid containing hydrogen peroxide to an evaporator and supplying the process gas to the substrate; and (c) supplying a microwave to the substrate after processing the substrate with the process gas.

### BRIEF DESCRIPTION OF THE DRAWINGS

FIG. 1 is a diagram schematically illustrating the structure of a substrate processing apparatus according to a first embodiment;

FIG. 2 is a schematic longitudinal cross-sectional view of a process furnace included in the substrate processing apparatus according to the first embodiment;

FIG. 3 is a diagram schematically illustrating the structure of a controller for use in substrate processing apparatuses according to the first embodiment to a third embodiment;

FIG. 4 is a flowchart of a substrate processing process according to the first embodiment;

FIG. 5 illustrates the structure of a hydrogen peroxide vapor generation device according to the first and second embodiments;

FIG. 6A is a schematic configuration diagram of an example of the vicinity of a furnace port according to the first to third embodiments;

FIG. 6B is a schematic configuration diagram of another example of the vicinity of a furnace port according to the first to third embodiments;

FIG. 7 is a diagram schematically illustrating an example of a location of a microwave source according to the first to third embodiments;

FIG. 8 is a diagram schematically illustrating the structure of a substrate processing apparatus according to the second embodiment;

FIG. 9 is a schematic longitudinal cross-sectional view of a process furnace included in the substrate processing apparatus according to the second embodiment;

FIG. 10 is a diagram schematically illustrating the structure of a substrate processing apparatus according to the third embodiment;

FIG. 11 is a schematic longitudinal cross-sectional view of a process furnace included in the substrate processing apparatus according to the third embodiment; and

FIG. 12 is a flowchart of a substrate processing process according to the third embodiment.

### DETAILED DESCRIPTION

### First Embodiment

Hereinafter, a first embodiment will be described.

### (1) Structure of Substrate Processing Apparatus

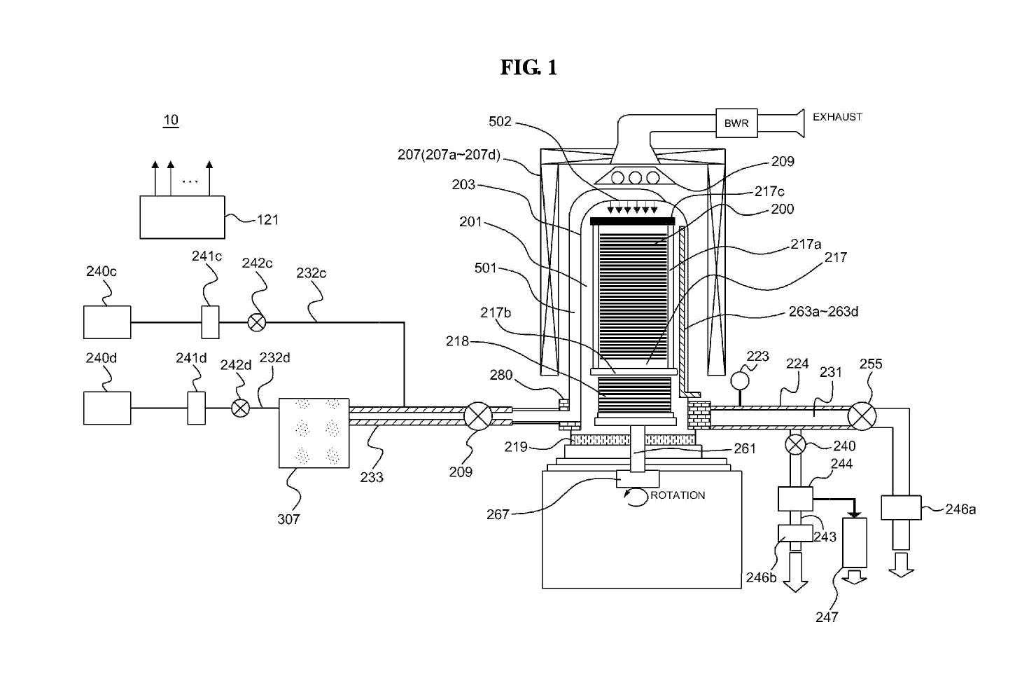

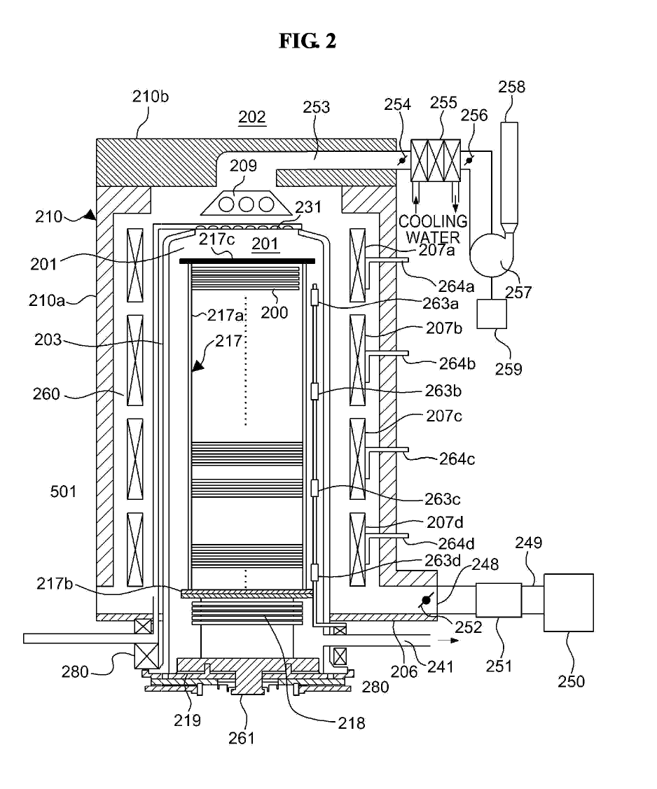

First, the structure of a substrate processing apparatus according to the present embodiment will be described mainly with reference to FIGS. 1 and 2. FIG. 1 is a diagram schematically illustrating the structure of a substrate processing apparatus according to the present embodiment FIG. 1, in which a longitudinal cross-section of a portion of a process furnace 202 is illustrated. FIG. 2 is a schematic longitudinal cross-sectional view of the process furnace 202 included in the substrate processing apparatus according to the present embodiment.

### (Reaction Tube)

As illustrated in FIG. 1, the process furnace 202 includes a reaction tube 203. The reaction tube 203 is formed of, for example, a heat-resistant material formed of at least one selected from the group consisting of quartz (SiO₂) and silicon carbide (SiC), and has a cylindrical shape, the top and bottom ends of which are open. A process chamber 201 is formed in a hollow tubular portion of the reaction tube 203, and configured to accommodate wafers 200 as substrates in a multistage manner using a boat 217 (which will be described below) such that the wafers 200 are vertically arranged in a horizontal posture.

Below the reaction tube 203, a seal cap 219 is installed as a furnace port lid for air-tightly sealing (closing) a lower end aperture (furnace port) of the reaction tube 203. The seal cap 219 is configured to come in contact with a lower end of the reaction tube 203 from below in a vertical direction. The seal cap 219 is formed in a disc shape. The process chamber 201 serving as a substrate processing space includes the reaction tube 203 and the seal cap 219.

### (Substrate Support)

The boat 217 serving as a substrate retainer is configured to retain a plurality of wafers 200 in a multistage manner. The boat 217 includes a plurality of pillars 217a configured to support the plurality of wafers 200. For example, the boat 217 includes three pillars 217a. Each of the plurality of pillars 217a is installed between a low plate 217b and a ceiling plate 217c. The plurality of wafers 200 are arranged in a horizontal posture and concentric form by the plurality of plurality of pillars 217a so that they may be retained in a multistage manner in a tube axial direction. The ceiling plate 217c is formed to be larger than a maximum external diameter of each of the wafers 200 retained on the boat 217.

The pillar 217a, the low plate 217b and the ceiling plate 217c are formed of, for example, a non-metal material having a high thermal conductive property, such as silicon carbide (SiC), aluminum oxide (AlO), aluminum nitride (AlN), silicon nitride (SiN), zirconium oxide (ZrO), etc. In particular, a non-metal material having a thermal conductivity of 10 W/mK or more is preferably used to form the pillar 217a, the low plate 217b and the ceiling plate 217c. If the thermal conductivity is not a concern, the pillar 217a, the low plate 217b and the ceiling plate 217c may be formed of quartz (SiO₂) or the like. If contamination of the wafer 200 by a metal is not a concern, the pillar 217a and the ceiling plate 217c may be formed of a metal material such as stainless steel (SUS). When a metal is used as a material of the pillar 217a and the ceiling plate 217c, a film may be formed on the metal using ceramics, Teflon™, etc.

An insulator 218 formed of, for example, a heat-resistant material such as quartz (SiO₂) or silicon carbide (SiC) is installed below the boat 217, and configured to prevent heat generated from a first heating unit 207 from being delivered to the seal cap 219. The insulator 218 functions as not only an insulating member but also a retainer for retaining the boat 217. The insulator 218 is not limited to a structure in which a plurality of insulating plates each having a disc shape are installed in a horizontal posture and a multistage manner as illustrated in FIGS. 1 and 2. For example, the insulator 218 may be a quartz cap formed in a disc shape. Also, the insulator 218 may be considered as one element of the boat 217.

### (Elevating Unit)

Below the reaction tube 203, a boat elevator is installed as an elevating unit configured to transfer the boat 217 to the inside or outside of the reaction tube 203 by moving the boat 217 upward or downward. At the boat elevator, the seal cap 219 is installed to close the furnace port when the boat 217 is lifted by the boat elevator.

A boat rotation mechanism 267 that rotates the boat 217 is installed at a side of the seal cap 219 opposite the process chamber 201. A rotation shaft 261 of the boat rotation mechanism 267 is connected to the boat 217 while passing through the seal cap 219, and configured to rotate the wafer 200 by rotating the boat 217.

### (First Heating Unit)

The first heating unit 207 is installed to surround sidewall surfaces of the reaction tube 203 in a concentric form at an outer side of the reaction tube 203 to heat the wafer 200 in the reaction tube 203. The first heating unit 207 is installed by being supported by a heater base 206. As illustrated in FIG. 2, the first heating unit 207 includes first to fourth heater units 207a through 207d. The first to fourth heater units 207a through 207d are each installed in a direction in which the wafers 200 are stacked in the reaction tube 203.

In the reaction tube 203, for the first to fourth heater units 207a through 207d, first to fourth temperature sensors 263a through 263d, e.g., thermocouples, are installed as temperature detectors between the reaction tube 203 and the boat 217 to detect temperatures of the wafers 200 or an ambient temperature. Also, each of the first to fourth temperature sensors 263a through 263d may be installed to detect the temperature of a wafer 200 located at a midpoint between a plurality of wafers 200 heated by the first to fourth heater units 207a through 207d, respectively.

The first heating unit 207 and the first to fourth temperature sensors 263a through 263d are electrically connected to a controller 121 which will be described below. The controller 121 is configured to control an amount of power to be supplied to each of the first to fourth heater units 207a through 207d at a predetermined timing, and individually set the temperatures of or perform temperature control on the first to fourth heater units 207a through 207d, such that the wafers 200 in the reaction tube 203 have a predetermined temperature, based on temperature information detected by each of the first to fourth temperature sensors 263a through 263d.

### (Gas Supply Unit)

As illustrated in FIG. 1, a gas supply pipe 233 serving as a gas supply unit for supplying a vaporizing source as a process gas into the reaction tube 203 is installed outside the reaction tube 203. As the vaporizing source, a source having a boiling point of 50° C. to 200° C. is used. In the present embodiment, the case in which a liquid containing hydrogen peroxide (H₂O₂) is used is presented. Water vapor (H₂O) may also be used, particularly when lower processing efficiency or quality is permissible.

As illustrated in FIG. 1, a hydrogen peroxide vapor generation unit 307 is connected to the gas supply pipe 233. A hydrogen peroxide solution source 240d, a liquid flow-rate controller 241d and a valve 242d are connected to the hydrogen peroxide vapor generation unit 307 via a hydrogen peroxide solution supply pipe 232d from an upstream end. The hydrogen peroxide vapor generation unit 307 is configured to supply flow-rate-controlled hydrogen peroxide to the liquid flow-rate controller 241d.

Also, an inert gas supply pipe 232c, a valve 242c, a mass flow controller (MFC) 241c and an inert gas source 240c are installed at the gas supply pipe 233 to supply an inert gas as in the first embodiment.

A gas supply unit includes a gas supply nozzle 501, gas supply holes 502, the gas supply pipe 233, the hydrogen peroxide vapor generation unit 307, the hydrogen peroxide solution supply pipe 232d, the valve 242d, the liquid flow-rate controller 241d, the inert gas supply pipe 232c, the valve 242c and the MFC 241c. The hydrogen peroxide solution source 240d or the inert gas source 240c may be included in a hydrogen peroxide vapor supply unit.

In the first embodiment, since hydrogen peroxide is used, an element that is in contact with hydrogen peroxide in the substrate processing apparatus is preferably formed of a material that hardly reacts with hydrogen peroxide. Examples of materials that hardly react with hydrogen peroxide may include ceramics such as Al₂O₃, AlN, SiC, etc. or quartz. Also, a reaction-preventing film is preferably formed on a metal member. For example, alumite (Al₂O₃) is formed on a member using aluminum, and a chromium oxide film is formed on a member using stainless steel. Also, a non-heated mechanism may be formed of a material that does not react with hydrogen peroxide, e.g., Teflon™ or a plastic.

### (Hydrogen Peroxide Vapor Generation Unit)

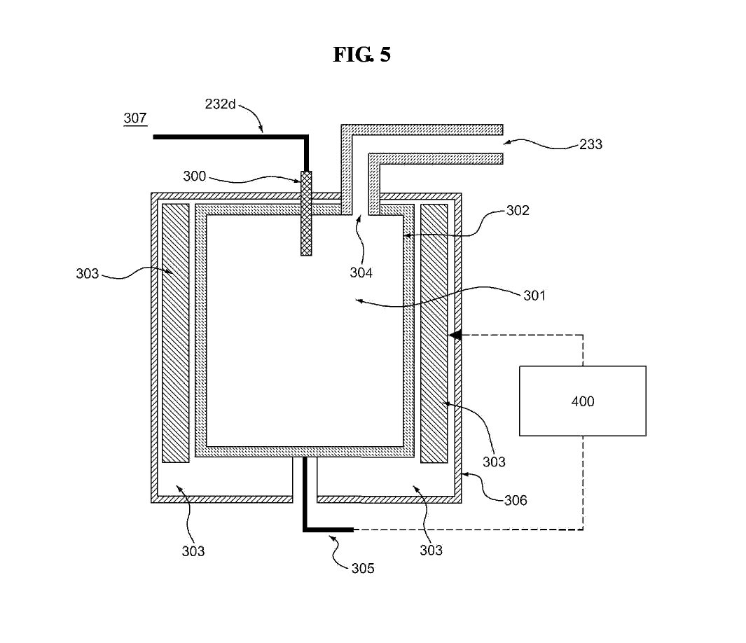

FIG. 5 illustrates the structure of a hydrogen peroxide vapor generation unit 307 configured to generate hydrogen peroxide vapor as a process gas. The hydrogen peroxide vapor generation unit 307 employs a dropping method of vaporizing a source liquid by supplying (or dropping) the source liquid onto a heated member. The hydrogen peroxide vapor generation unit 307 includes a dropping nozzle 300 serving as a liquid supply unit configured to supply a hydrogen peroxide solution, a vaporizing container 302 serving as a heating member, a vaporizing space 301 configured by the vaporizing container 302, a vaporizer heater 303 serving as a heating unit configured to heat the vaporizing container 302, an exhaust port 304 configured to exhaust a vaporized source liquid to the reaction tube 203, a thermocouple 305 configured to measure a temperature of the vaporizing container 302, a temperature controller 400 configured to control a temperature of the vaporizer heater 303 based on the temperature measured by the thermocouple 305 and a hydrogen peroxide solution supply pipe 232d configured to supply a source liquid to the dropping nozzle 300. The vaporizing container 302 is heated by the vaporizer heater 303 so that a dropped source liquid may be vaporized the moment the dropped source liquid is delivered to the vaporizing container 302. As described above, a liquid containing a mixture of materials having different boiling points and a gas thereof may be vaporized by dropping the liquid and the gas without changing the concentrations thereof. For example, hydrogen peroxide and water contained in a hydrogen peroxide solution have different boiling points. When the hydrogen peroxide solution is gradually heated to be vaporized, the water first evaporates and then the hydrogen peroxide evaporates. Thus, the concentration of the hydrogen peroxide changes right after the vaporization of the hydrogen peroxide solution starts. Also, an insulator 306 capable of improving the efficiency of heating the vaporizing container 302 by the vaporizer heater 303 or insulating the hydrogen peroxide vapor generation unit 307 and other units from one another is installed. The vaporizing container 302 is formed of quartz, silicon carbide, etc. to prevent it from reacting with a source liquid. The temperature of the vaporizing container 302 is lowered according to the temperature of a dropped source liquid or by heat of vaporization. Thus, in order to prevent a decrease in the temperature of the vaporizing container 302, it is effective to use silicon carbide having thermal conductivity. Although the dropping method is used here, if the temperature of the vaporizing container 302 does not change even when a heated member is sufficiently heated, the source liquid may be continuously supplied or sprayed in a grain form.

### (Exhaust Unit)

One end of a gas exhaust pipe 231 configured to exhaust a gas from the inside of the process chamber 201 is connected to the bottom of the reaction tube 203. The other end of the gas exhaust pipe 231 is connected to a vacuum pump 246a (exhaust device) via an auto pressure controller (APC) valve 255. The inside of the process chamber 201 is exhausted using negative pressure generated by the vacuum pumps 246a and 246b. The APC valve 255 is an opening/closing valve configured to perform or suspend exhaust in the process chamber 201 by opening/closing the APC valve 255. The APC valve 255 also functions as a pressure control valve configured to adjust the inner pressure of the process chamber 201 by controlling the degree of openness of the APC valve 255. Also, a pressure sensor 223 serving as a pressure detector is installed at an upstream side of the APC valve 255. Thus, the inner pressure of the process chamber 201 is set to be vacuum-exhausted to a desired pressure (degree of vacuum). A pressure control unit is electrically connected to the process chamber 201 and the pressure sensor 223 via the APC valve 255. The pressure control unit is configured to control the inner pressure of the process chamber 201 to be equal to a desired pressure using the APC valve 255 at a desired timing, based on a pressure measured by the pressure sensor 223.

An exhaust unit includes the gas exhaust pipe 231, the APC valve 255, the pressure sensor 223, etc. The vacuum pump 246a may be further included in the exhaust unit.

### (Exhaust and Heating Unit)

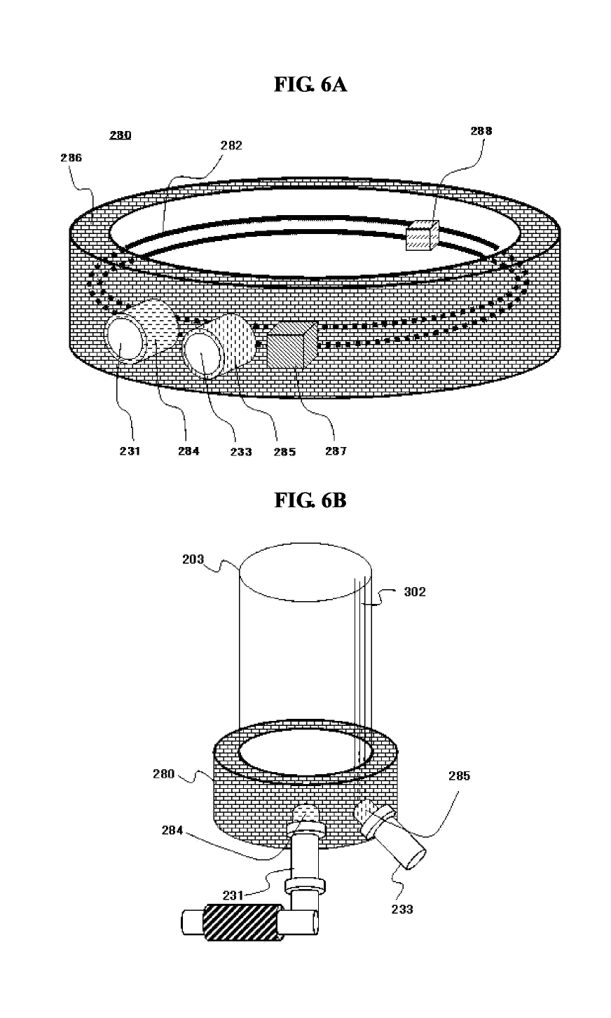

As illustrated in FIGS. 6A and 6B, an exhaust tube heater 284 serving as an exhaust heating unit for heating the gas exhaust pipe 231 is installed at the gas exhaust pipe 231. The exhaust tube heater 284 controls the inside of the gas exhaust pipe 231 to have a desired temperature so that dew condensation does not occur in the gas exhaust pipe 231. For example, the inside of the gas exhaust pipe 231 is controlled to have a temperature of 50° C. to 300° C.

### (Supply and Heating Unit)

As illustrated in FIGS. 6A and 6B, an inlet tube heater 285 serving as a supply and heating unit is installed between the gas supply pipe 233 and the reaction tube 203. The inlet tube heater 285 is controlled to have a desired temperature such that dew condensation does not occur in the inside of the gas supply pipe 233. For example, the temperature of the inlet tube heater 285 is controlled to be in the range of 50° C. to 300° C.

Although the gas supply pipe 233 and the gas exhaust pipe 231 are installed in opposite locations in FIGS. 1 and 2, they may be installed at the same side. Since an empty space in the substrate processing apparatus or an empty space in a semiconductor device factory in which a plurality of substrate processing apparatuses are installed is narrow, the gas supply pipe 233, the gas exhaust pipe 231 and a second heating unit (anti-liquefaction heater) 280 may be easily maintained when the gas supply pipe 233 and the gas exhaust pipe 231 are installed at the same side.

### (Control Unit)

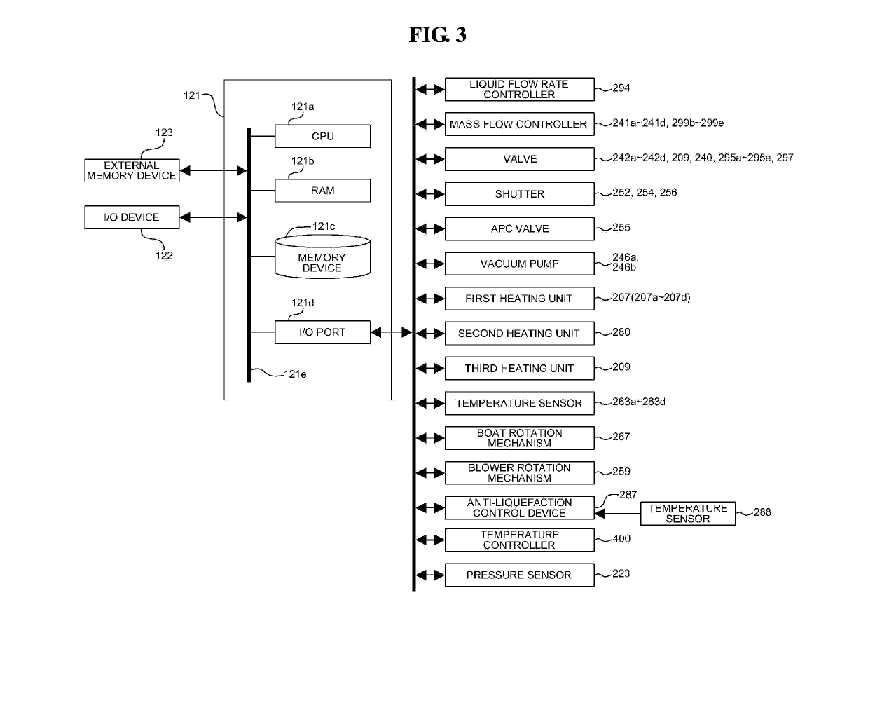

As illustrated in FIG. 3, the controller 121 which is a control unit (control means) is configured as a computer that includes a central processing unit (CPU) 121a, a random access memory (RAM) 121b, a memory device 121c and an input/output (I/O) port 121d. The RAM 121b, the memory device 121c and the I/O port 121d are configured to exchange data with the CPU 121a via an internal bus 121e. An I/O device 122 configured as a touch panel or the like is connected to the controller 121.

The memory device 121c is configured, for example, as a flash memory, a hard disk drive (HDD), etc. In the memory device 121 c, a control program for controlling an operation of a substrate processing apparatus, a process recipe including the order or conditions of substrate processing which will be described below, or the like is stored to be readable. The process recipe is a combination of sequences of a substrate processing process which will be described below to obtain a desired result when the sequences are performed by the controller 121, and acts as a program. Hereinafter, the process recipe, the control program, etc. will be referred to together simply as a ‘program.’ When the term ‘program’ is used in the present disclosure, it may be understood as including only a process recipe, only a control program, or both of the process recipe and the control program. The RAM 121b is configured as a memory area (work area) in which a program or data read by the CPU 121a is temporarily stored.

The I/O port 121d is connected to a liquid flow-rate controller 294, MFCs 241a, 241b, 241c, 241d, 299b, 299c, 299d and 299e, valves 242a, 242b, 242c, 242d, 209, 240, 295a, 295b, 295c, 295d and 295e, shutters 252, 254 and 256, the APC valve 255, the first heating unit 207 (the first to fourth heater units 207a, 207b, 207c and 207d), the third heating unit 209, a blower rotation mechanism 259, the first to fourth temperature sensors 263a through 263d, the boat rotation mechanism 267, an anti-liquefaction control device 287, the pressure sensor 223, the temperature controller 400, etc.

The CPU 121a is configured to read and execute the control program from the memory device 121c and to read the process recipe from the memory device 121c according to a manipulation command or the like received via the I/O device 122. The CPU 121a is configured to, based on the read process recipe, control the flow rate of a liquid source using the liquid flow-rate controller 294; control the flow rates of various gases via the MFCs 241a, 241b, 241c, 241d, 299b, 299c, 299d and 299e; control opening/closing of the valves 242a, 242b, 242c, 242d, 209, 240, 295a, 295b, 295c, 295d and 295e; control blocking operations of the shutters 252, 254 and 256; control opening/closing of the APC valve 255 and control a temperature using the first heating unit 207 based on the first to fourth temperature sensors 263a through 263d; control a temperature using the third heating unit 209 based on a temperature sensor; control driving/suspending of the vacuum pumps 246a and 246b; control the rotation speed of the blower rotation mechanism 259; control the rotation speed of the boat rotation mechanism 267; control a temperature of the second heating unit 280 using the anti-liquefaction control device 287; and control the hydrogen peroxide vapor generation unit 307 using the temperature controller 400.

The controller 121 is not limited to a dedicated computer and may be configured as a general-purpose computer. For example, the controller 121 according to the present embodiment may be configured by providing an external memory device 123 storing a program as described above, e.g., a magnetic disk (e.g., a magnetic tape, a flexible disk, a hard disk, etc.), an optical disc (e.g., a compact disc (CD), a digital versatile disc (DVD), etc.), a magneto-optical (MO) disc, or a semiconductor memory (e.g., a Universal Serial Bus (USB) memory, a memory card, etc.) and then installing the program in a general-purpose computer using the external memory device 123. However, the means for supplying a program to a computer is not limited to using the external memory device 123. For example, a program may be supplied to a computer using a communication means, e.g., the Internet or an exclusive line, without using the external memory device 123. The memory device 121c or the external memory device 123 may be configured as a non-transitory computer-readable recording medium. Hereinafter, the memory device 121c and the external memory device 123 may also be referred to together simply as a ‘recording medium.’ When the term ‘recording medium’ is used in the present disclosure, it may be understood as only the memory device 121c, only the external memory device 123, or both of the memory device 121c and the external memory device 123.

### (2) Substrate Processing Process

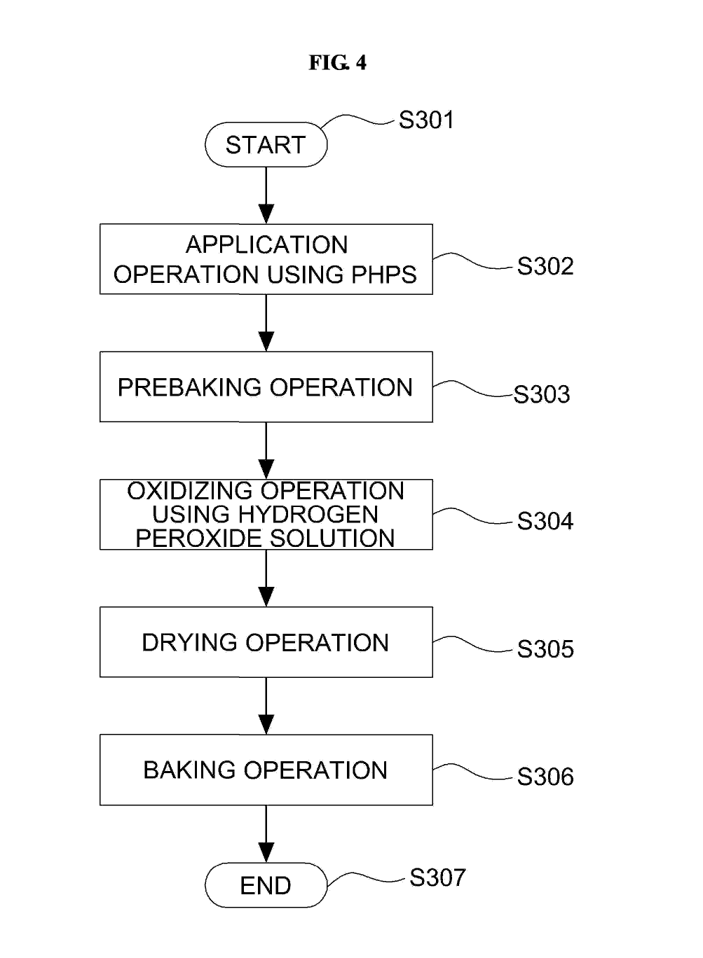

A substrate processing process according to the first embodiment of the present invention is illustrated in FIG. 4. The substrate processing process according to the first embodiment includes an application operation of applying a material of an oxide film to be formed according to an application method (operation S302), a prebaking operation of drying a solvent component contained in the oxide film after the material of the oxide film is applied (operation S303), an oxidation operation of exposing the resultant oxide film to a hydrogen peroxide solution or plunging the resultant oxide film into the hydrogen peroxide solution after the solvent component is dried (operation S304) and a drying operation of cleaning the resultant oxide film with pure water and drying the cleaned resultant oxide film after the resultant oxide film is exposed to or plunged into the hydrogen peroxide solution (operation S305).

In the application operation (operation S302), a material of an oxide film is applied on a wafer 200, which is loaded in a process chamber, by spin coating. Here, the material of the oxide film is perhydro-polysilazane (PHPS). A fine concavo-convex structure is formed on the wafer 200. The fine concavo-convex structure is formed, for example, by a trench of a gate insulating film, a gate electrode, or a fine semiconductor device.

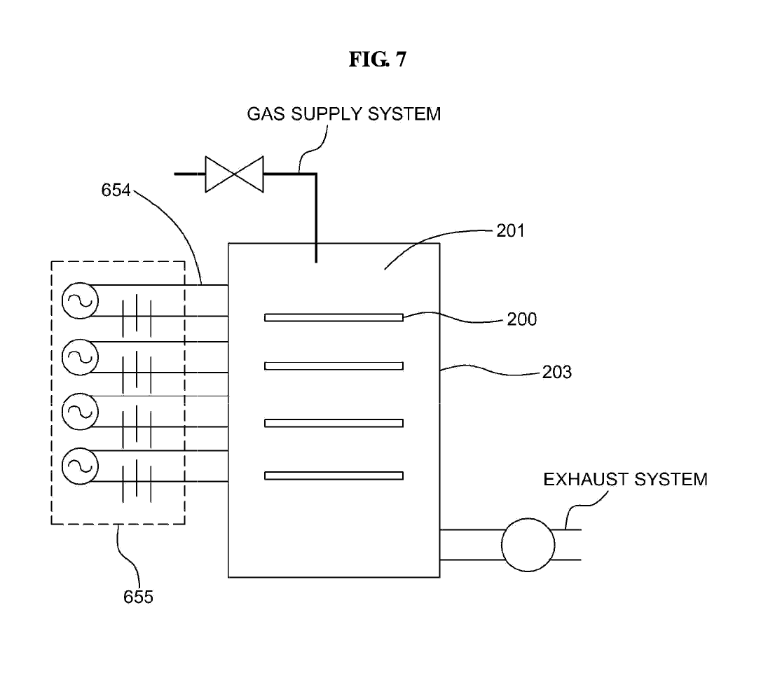

In the prebaking operation (operation S303), prebaking is performed to cure the PHPS by heating the wafer 200 on which the PHPS is applied and vaporizing a solvent contained in the applied PHPS. The heating of the wafer 200 is performed by a heating unit installed in the process chamber. The heating unit includes a microwave source which will be described below (see FIG. 7). Alternatively, a plurality of wafers 200 may be simultaneously heated in a state in which they are accommodated in the process chamber.

In the oxidation operation using the hydrogen peroxide solution (operation S304), the hydrogen peroxide solution is supplied to the wafer 200 on which a PHPS film is formed. By supplying the hydrogen peroxide solution to the wafers 200, the PHPS film is oxidized to form a silicon oxide film. The supply of the hydrogen peroxide solution to the wafer 200 is performed while rotating the wafer 200.

The oxidation operation using the hydrogen peroxide solution (operation S304) will be described in more detail below. When the wafer 200 is heated to a desired temperature and the speed of rotating the boat 217 reaches a desired speed, supply of the hydrogen peroxide solution to the hydrogen peroxide vapor generation unit 307 via the hydrogen peroxide solution supply pipe 232d is started. That is, the valve 242d is opened to supply the hydrogen peroxide solution into the hydrogen peroxide vapor generation unit 307 from the hydrogen peroxide solution source 240d via the liquid flow-rate controller 241d.

The hydrogen peroxide solution supplied to the hydrogen peroxide vapor generation unit 307 is dropped to the bottom of the vaporizing container 302 via the dropping nozzle 300. The vaporizing container 302 is heated to a desired temperature (e.g., 150° C. to 170° C.) by the vaporizer heater 303, and a droplet of the dropped hydrogen peroxide is heated and vaporized into a gas.

The gas of the hydrogen peroxide solution is supplied to the wafer 200 accommodated in the process chamber 201 via the gas supply pipe 233, a gas supply nozzle 401 and gas supply holes 402.

A silicon-containing film formed on the wafer 200 is modified into a SiO film through an oxidation reaction between the gas of the hydrogen peroxide solution and a surface of the wafer 200.

The hydrogen peroxide (H₂O₂) solution has a simple structure in which molecules of hydrogen are bound to molecules of oxygen and may thus easily penetrate a low-density medium. When the hydrogen peroxide solution decomposes, hydroxyl radicals (OH*) are produced. A hydroxyl radical is a type of active oxygen and is a neutral radical in which oxygen and hydrogen are bound to each other. Hydroxyl radicals have strong oxidizing power. Due to the hydroxyl radicals produced when the supplied hydrogen peroxide solution decomposes, the silicon-containing film (PHPS film) on the wafer 200 is oxidized to form a silicon oxide film. That is, a silazane bond (Si—N bond) or a Si—H bond in the silicon-containing film is broken by the oxidizing power of the hydroxyl radicals. Then, nitrogen (N) atoms or hydrogen (H) atoms separated from the silazane bonds (Si—N bond) or the Si—H bonds are replaced with the oxygen (O) atoms contained in the hydroxyl radicals and thus Si—O bonds are formed in the silicon-containing film. As a result, the silicon-containing film is oxidized and modified into a silicon oxide film. Even when a film having a fine concavo-convex structure is formed on the wafer 200, the hydrogen peroxide solution may uniformly penetrate the silicon-containing film filled in the concavo-convex structure from top to bottom.

The hydrogen peroxide solution is exhausted from the vacuum pump 246b and a liquid collecting tank 247 while the hydrogen peroxide solution is supplied into the reaction tube 203. That is, the APC valve 255 is closed, the valve 240 is opened, and an exhaust gas exhausted from the reaction tube 203 is caused to pass through the inside of the a separator 244 through the gas exhaust pipe 231 via a second exhaust pipe 243. Then the exhaust gas is divided into a liquid that contains hydrogen peroxide and a gas that does not contain hydrogen peroxide by the separator 244, the gas is exhausted through the vacuum pump 246b, and the liquid is collected into the liquid collecting tank 247.

When the hydrogen peroxide solution is supplied into the reaction tube 203, the valve 240 and the APC valve 255 may be closed and pressure may be applied to the inside of the reaction tube 203. Thus, an atmosphere of the hydrogen peroxide solution in the reaction tube 203 may be controlled to be uniform.

After a predetermined time elapses, the valve 242d is closed to stop the supply of the hydrogen peroxide solution into the reaction tube 203.

Although it is described that the hydrogen peroxide solution is supplied to the hydrogen peroxide vapor generation unit and the hydrogen peroxide gas is supplied into the process chamber 201, the present invention is not limited thereto and, for example, a liquid containing ozone (O₃) may be used. Water vapor (H₂O) may also be used, particularly when lower processing efficiency or quality is permissible.

According to another embodiment, a liquid storage tank may be installed in a process chamber, a hydrogen peroxide solution may be contained in the liquid storage tank beforehand, and the wafer 200 may be plunged into the hydrogen peroxide solution.

In the drying operation (operation S305), pure water is supplied to the wafer 200 to remove hydrogen peroxide or byproducts, and then the wafer 200 is dried. The supplying of the pure water is preferably performed by rotating the wafer 200. The pure water is supplied using a pure water supply nozzle (not shown). The drying of the wafer 200 is performed by rotating the wafer 200. By rotating the wafer 200, a centrifugal force is applied to moisture on the wafer 200, thereby removing the moisture from the water 200. Otherwise, the drying of the wafer 200 may be performed by supplying alcohol to replace the moisture with the alcohol, and removing the alcohol. The alcohol that is in a vapor form is supplied to the wafer 200. Otherwise, an alcohol solution may be dropped onto the wafer 200. Otherwise, a heating element (not shown) may be installed in the process chamber 201, and the removing of the alcohol may promoted by heating the wafer 200 to a moderate temperature. The heating element may be, for example, a lamp heater (not shown), a resistance-heating heater (not shown), or the like. The alcohol may be, for example, isopropyl alcohol (IPA). Also, the drying operation (operation S305) may be performed in a state in which a plurality of wafers 200 are accommodated in the process chamber 201.

Next, the baking operation (operation S306) of heating the wafer 200 after the wafer 200 is dried will be described. In the baking operation (operation S306), the wafer 200 on which the silicon oxide film is formed is heated. In detail, after a nitrogen atmosphere is formed in the process chamber, the wafer 200 is heated to a temperature that is in the range of 150° C. to 500° C. The wafer 200 is preferably heated to a temperature that is in the range of 200° C. to 400° C., e.g., to 200° C. The heating of the wafer 200 is performed using a microwave source which will be described below (see FIG. 7). Also, the wafer 200 may be heated while an oxygen-containing gas is supplied into the process chamber. For example, the oxygen-containing gas may be oxygen (O₂) gas, water vapor (H₂O), ozone (O₃) gas, nitric oxide (NO) gas, nitrogen dioxide (NO₂) gas, etc. Alternatively, a plurality of wafers 200 may be heated in a state in which they are accommodated in the process chamber 201.

The application operation (operation S302) to the baking operation (operation S306) may be performed in the same process chamber. Otherwise, an application process chamber in which the application operation is performed, a prebaking process chamber in which the prebaking operation is performed, a baking process chamber in which an oxidizing and drying operation including the oxidizing operation and the drying operation is performed and the baking operation is performed, etc. may be separately performed to individually perform these operations.

### (Microwave Source)

FIG. 7 illustrates an example of a microwave source serving as an electromagnetic wave source. A microwave source 655 is installed at a side surface of the reaction tube 203, and applies microwaves or millimeter waves for thirty minutes, for example, at a frequency of 1 GHz to 100 GHz. Thus, the temperature of the wafer 200 is increased to a temperature that is in the range of 100° C. to 450° C., e.g., to 400° C. That is, the microwave source 655 supplies microwaves or millimeter waves into the process chamber 201 via a waveguide 654. The microwaves supplied into the process chamber 201 are incident on the wafer 200 and very effectively increase the temperature of the wafer 200 so that the microwaves may be efficiently absorbed into the wafer 200. Also, microwaves with power corresponding to the product of the intensity of the power of the microwaves and the number of wafers may be supplied to one wafer. The frequency of the microwaves is variable while the microwaves are supplied. By supplying the microwaves while changing the frequency of the microwaves, the microwaves may be diffused to the entire process chamber 201, thereby improving the quality of processing a substrate. Also, even if hydrogen and oxygen are bound to each other in various states, the wafer 200 may be uniformly processed by changing the frequency of the microwaves. When a film having a fine concavo-convex structure is formed on the wafer 200, hydrogen peroxide or water may be uniformly contained in a silicon-containing film filled in the fine concavo-convex structure from top to bottom. The hydrogen peroxide or water may be heated by microwaves and thus the silicon-containing film filled in the concavo-convex structure may be uniformly processed from top to bottom.

Although the case in which a plurality of power sources are used has been described above, one power source may be prepared for each wafer and a distributor may not be installed.

In the present embodiment, when a plurality of wafers are processed in a batch, the throughput may be improved far more than when one of the plurality of wafers is processed at a time.

In a single-wafer type substrate processing apparatus, when microwaves are vertically incident on a surface of a wafer, a certain component is reflected from the wafer. On the other hand, in a vertical substrate processing apparatus according to the present embodiment, microwaves are incident on a side surface of a wafer and thus a certain component may be prevented from being reflected from an uppermost wafer adjacent to a waveguide, compared to when microwaves are vertically incident.

An advantage obtained when a wafer is heated using microwaves in a baking operation according to the present invention will be described below. Microwaves are a type of electromagnetic waves. It is known that microwaves are almost entirely transmitted through quartz, which is a nearly pure silicon oxide, but microwaves are transmitted through polymers such as silicones or epoxy resins to a depth of several tens of centimeters to several meters. While microwaves are transmitted through an object, the energy of the microwaves is absorbed into the object when a dipole in the object is rotationally vibrated. When the energy of the microwaves is absorbed, the structure of the vicinity of the dipole is expected to be optimized. The above principle is applied in a microwave oven, in which moisture, which is a dipole, in food is rotationally heated at a fixed frequency of 2.45 GHz. To modify polysilazane, polysilazane is oxidized by adding moisture to polysilazane in an oxidizing operation using a hydrogen peroxide solution. The moisture is a vibrating factor of microwaves. The structure of a film becomes dense by absorbing and vibrating moisture in polysilazane and absorbing and heating a silicone which is a lower substrate of polysilazane.

When heating is performed in a nitrogen atmosphere at an atmospheric pressure without using microwaves after the oxidizing operation, energy for polysilazane propagates mainly through thermal vibration caused when a nitrogen molecule collides against an object and radiation of heat from a heater. Heat propagates to a nitrogen molecule by delivering energy of the heat when the energy collides against a target object through translation, rotation, or expansion and contraction exercise. The propagating energy propagates through the object through conduction electrons of the object or lattice vibration. That is, for heat conduction performed without using microwaves, energy propagates with respect to a surface of a target material as a starting point. The propagation of the energy has a strong influence on the surface of the target material. An electrically insulated material such as an oxide film or diamond contributes fewer conduction electrons, and lattice vibration is a main factor that propagates energy. Thus, lattice vibration is a factor that degrades the efficiency of heat conduction in a place in which discontinuous lattices or lattice mismatch occurs. Thus, in a heating method using microwaves, a mechanism related to a match between a frequency and a target object is still unclear but energy may propagate through the target object and may be delivered in units of dipoles. Thus, a film is expected to be effectively densified when the heating method is used.

Although all operations are performed in the same process chamber in the present embodiment, the operations may be performed in different process chambers (e.g., an application process chamber in which an application operation is performed, a prebake process chamber in which a prebaking operation is performed, and an oxidizing and drying process chamber in which an oxidizing operation and a drying operation are performed, etc.) may be installed.

Also, when the wafers 200 are processed in different process chambers, two or more wafers 200 may be also simultaneously processed in a batch in each of the operations. When two or more substrates are simultaneously processed, the substrate processing throughput may be improved.

Although a case in which heating using a microwave source is performed in the baking operation (operation S306) has been described above, the present invention is not limited thereto and heating using a microwave source may be performed in an oxidizing operation using a hydrogen peroxide solution. By supplying microwaves, water molecules in H₂O₂ may be activated to increase the amount of hydroxyl radicals to be generated, thereby improving the processing throughput.

### (4) Effects of the First Embodiment

According to the present embodiment, the following one or more effects may be obtained.

(a) According to the present embodiment, after PHPS is applied, a time required to oxidize the PHPS and form a silicon oxide film and a standby time therefor, i.e., a lead time, may be decreased.

(b) Since a series of operations is performed in the same housing, a reaction between a PHPS-coated film generated right after PHPS is applied and moisture in air may be prevented. Thus, reproducible processing is performed in every lot. Also, since a fine concavo-convex structure is formed, a surface of the wafer 200 may be uniformly processed even if a surface area of the wafer 200 is large.

(c) Since a series of operations is performed in the same housing, unexpected environmental influences such as adsorption of siloxane or the like present in a clean room environment of a semiconductor device manufacturing factory, adsorption of chemical components, or electrostatic charges may be suppressed from occurring.

(d) Since, in a baking operation, baking is performed on the wafer 200 using microwaves, a silicon oxide film formed on the wafer 200 may be modified. For example, the silicon oxide film may be densified. Also, since a film that is likely to absorb microwaves is heated and a film that hardly absorbs the microwaves is not heated, a film formed on a substrate may be selectively heated.

(e) In the baking operation, by heating the wafer 200 to a temperature of 200° C. to 400° C., a silicon oxide film formed of PHPS may be modified without deteriorating the features of a gate oxide film or a gate electrode formed on the wafer 200.

(f) Nitrogen and hydrogen contained in polysilazane may be replaced with oxygen due to wafer molecules, thereby forming Si—O bonds.

(g) A silicon oxide film that does not contain a large amount of NH— and that has a main skeleton of Si—O bonds may be generated from a silicon-containing film. The silicon oxide film has a high heat-resistance property, compared to the existing silicon oxide film formed of organic SOG.

(h) Since processing is performed at a low temperature, a groove in a fine structure may be uniformly processed, compared to when processing is performed at a high temperature. When processing is performed at a high temperature, the top of the groove may be modified first and the bottom of the groove may not be modified. However, when processing is performed at a low temperature, the top of the groove may be prevented from being modified first when the processing of the groove starts, and the inside of the groove may be uniformly processed.

(i) Since baking is performed using microwaves, impurities, e.g., nitrogen or hydrogen, may be removed from a silicon-containing film in a deepest portion of a groove in the wafer 200. Thus, the silicon-containing film may be sufficiently oxidized, densified and cured and may thus exhibit high wafer etching rate (WER) characteristics as an insulating film. Since the WER largely depends on a final baking temperature, the WER characteristics are improved at a higher temperature.

(j) Since baking is performed using microwaves, carbon (C) or impurities contained in a silicon-containing film may be removed. In general, the silicon-containing film is formed using an application method, e.g., spin coating. In spin coating, a liquid in which an organic solvent is added to polysilazane is used, and carbon or other impurities (elements other than Si and O) derived from the organic solvent remain.

(k) When the gas supply pipe 233 and the gas exhaust pipe 231 are installed at the same side, they may be easily maintained.

Although the first embodiment has been described in detail above, the first embodiment is not limited to that described above and may be embodied in many different forms without departing from the scope of the invention.

### Second Embodiment

A second embodiment will be described below.

### (1) Structure of Substrate Processing Apparatus

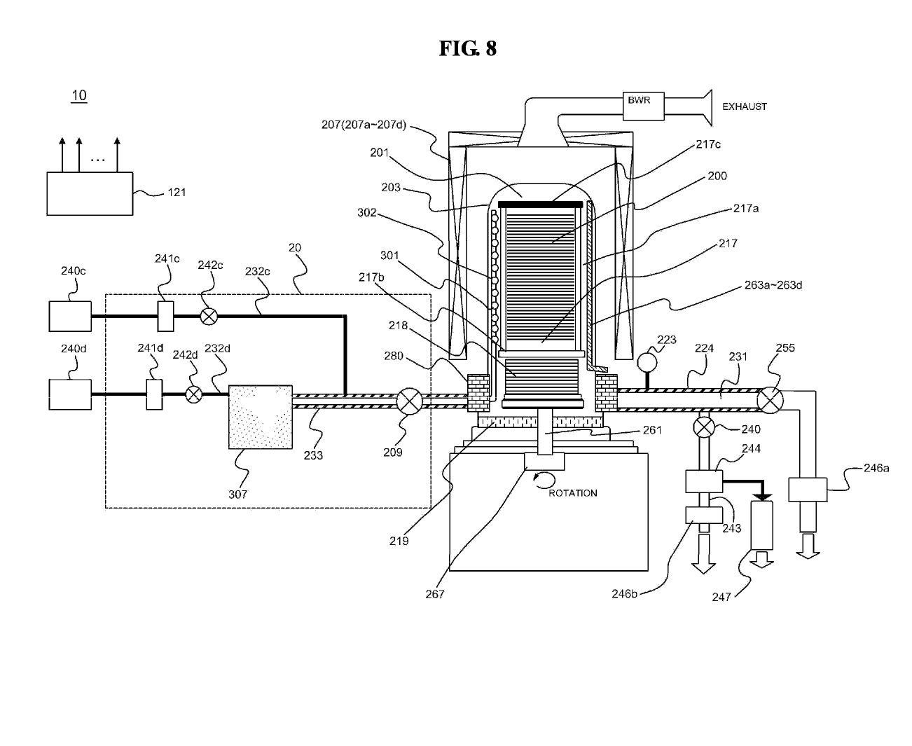

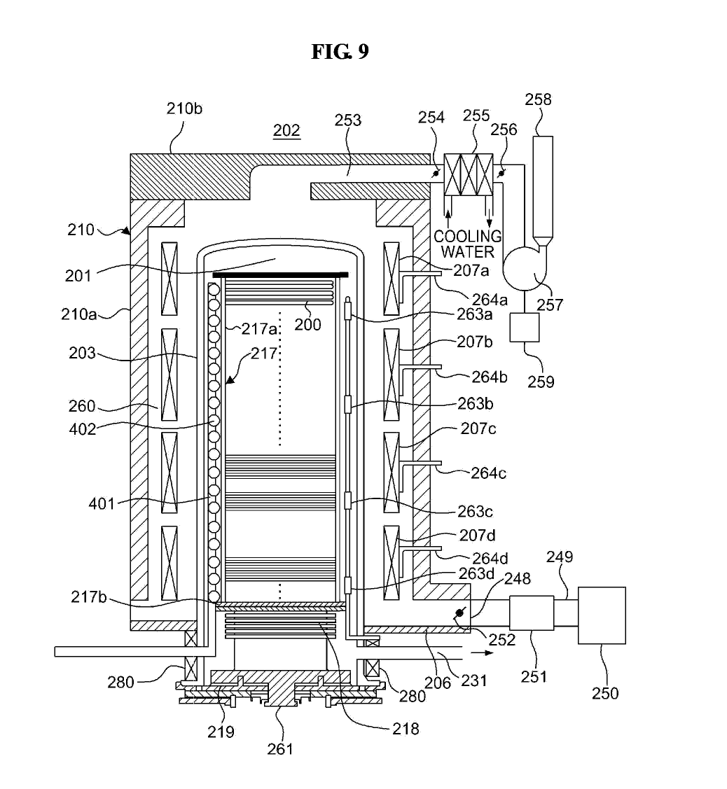

First, the structure of a substrate processing apparatus according to the second embodiment will be described with reference to FIGS. 8 and 9. FIG. 8 is a diagram schematically illustrating the structure of a substrate processing apparatus according to the present embodiment, in which a portion of a process furnace 202 is illustrated in a longitudinal cross-sectional view. FIG. 9 is a schematic longitudinal cross-sectional view of the process furnace 202 included in the substrate processing apparatus according to the second embodiment.

A gas is supplied to the top of the process chamber 201 in the first embodiment, whereas a gas is supplied to a substrate to be parallel to the substrate from a direction of a side of the substrate using a gas supply nozzle in the substrate processing apparatus according to the second embodiment. Parts of the second embodiment that are the same as those of the first embodiment are not described again here.

### (Gas Supply Unit)

As illustrated in FIG. 8, a hydrogen peroxide vapor generation unit 307 is connected to a gas supply pipe 233. A hydrogen peroxide solution source 240d, a liquid flow-rate controller 241d and a valve 242d are connected to the hydrogen peroxide vapor generation unit 307 via a hydrogen peroxide solution supply pipe 232d from an upstream end. The hydrogen peroxide vapor generation unit 307 is configured to supply a hydrogen peroxide solution, the flow rate of which is controlled by the liquid flow-rate controller 241d.

An inert gas supply pipe 232c, a valve 242c, an MFC 241c and an inert gas source 240c are installed at the gas supply pipe 233 to supply an inert gas, as in the first embodiment.

A gas supply unit includes a gas supply nozzle 401, gas supply holes 402, the gas supply pipe 233, the hydrogen peroxide vapor generation unit 307, the hydrogen peroxide solution supply pipe 232d, the valve 242d, the MFC 241d, the inert gas supply pipe 232c, the valve 242c and the MFC 241c. The hydrogen peroxide solution source 240d or the inert gas source 240c may be included in a hydrogen peroxide vapor supply unit.

### (2) Substrate Processing Process

A substrate processing process according to the second embodiment is substantially the same as that according to first embodiment and thus will not be described again here.

### (3) Effects of the Second Embodiment

The effects of the second embodiment are substantially the same as those of the first embodiment.

The inventors of the present application have conducted further research and found that when hydrogen peroxide is vaporized in the process chamber 201, the hydrogen peroxide may be prevented from being liquefied, as will be described in a third embodiment below.

### Third Embodiment

The third embodiment will be described below.

### (1) Structure of Substrate Processing Apparatus

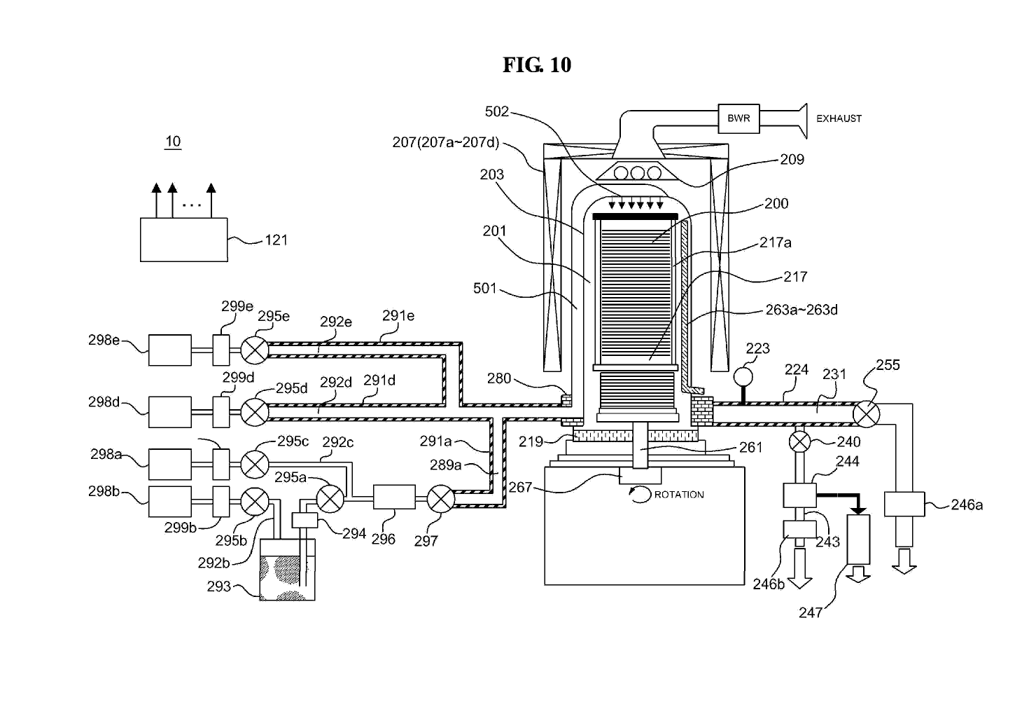

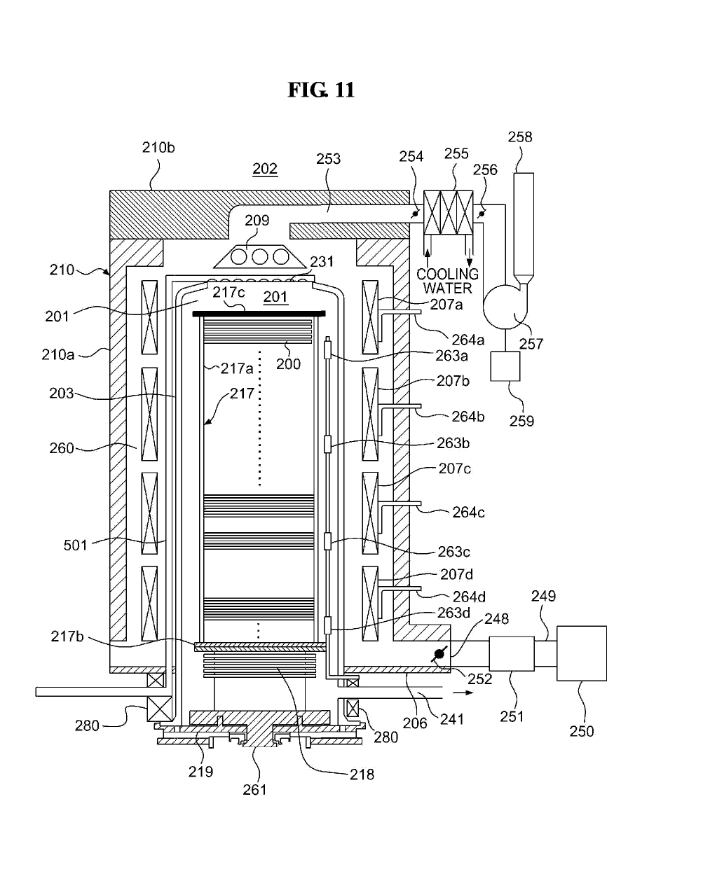

First, the structure of a substrate processing apparatus according to the third embodiment will be described with reference to FIGS. 10 and 11 below. FIG. 10 is a diagram schematically illustrating the structure of a substrate processing apparatus according to the third embodiment, in which a portion of a process furnace 202 is illustrated in a longitudinal cross-sectional view. FIG. 11 is a schematic longitudinal cross-sectional view of the process furnace 202 included in the substrate processing apparatus according to the third embodiment.

### (Gas Supply Unit)

As illustrated in FIG. 10, a liquid source supply nozzle 501 is installed between a reaction tube 203 and a first heating unit 207. The liquid source supply nozzle 501 is formed of, for example, quartz having low thermal conductivity. The liquid source supply nozzle 501 may have a double pipe structure. The liquid source supply nozzle 501 is installed along a side portion of an external wall of a reaction tube 203. A top end (downstream end) of the liquid source supply nozzle 501 is air-tightly installed at a peak portion (top end opening) of the reaction tube 203. A plurality of supply holes 502 are installed at the liquid source supply nozzle 501 located at the top end opening of the reaction tube 203 from an upstream end to the downstream end. The plurality of supply holes 502 are formed to spray a liquid source supplied into the reaction tube toward a ceiling plate 217c of a boat 217 accommodated in the reaction tube 203.

A downstream end of a liquid source supply pipe 289a configured to supply a liquid source is connected to the upstream end of the liquid source supply nozzle 501. A liquid source supply tank 293, a liquid flow-rate controller 294 which is a liquid flow rate controller (liquid flow rate control unit), a valve 295a which is an opening/closing valve, a separator 296 and a valve 297 which is an opening/closing valve are sequentially installed at the liquid source supply pipe 289a from an upstream end. A sub-heater 291a is installed at the liquid source supply pipe 289a at at least a downstream side of the valve 297.

A downstream side of a transfer gas supply pipe 292b configured to supply a gas to be transferred is connected to the top of the liquid source supply tank 293. A transfer gas supply source 298b, an MFC 299b which is a flow rate controller (flow rate control unit) and a valve 295b which is an opening/closing valve are sequentially installed at the transfer gas supply pipe 292b from an upstream end.

A third heating unit 209 is installed in an external upper portion of the reaction tube 203. The third heating unit 209 is configured to heat the ceiling plate 217c of the boat 217. The third heating unit 209 may be, for example, a lamp heater unit or the like. A controller 121 is electrically connected to the third heating unit 209. The controller 121 is configured to control an amount of power to be supplied to the third heating unit 209 at a predetermined timing such that the ceiling plate 217c of the boat 217 has a predetermined temperature.

An inert gas supply pipe 292c is connected between the valve 295a of the liquid source supply pipe 289a and the separator 297. A an inert gas source 298, an MFC 299c which is a flow rate controller (flow rate control unit) and a valve 295c which is an opening/closing valve are sequentially installed at the inert gas supply pipe 292c from an upstream end.

A downstream end of a first gas supply pipe 292d is connected to the liquid source supply pipe 289a at a downstream side of the valve 297. A source gas supply source 298d, an MFC 299d which is a flow rate controller (flow rate control unit) and a valve 295d which is an opening/closing valve are sequentially installed at the first gas supply pipe 292d from an upstream end. A sub-heater 291d is installed at the first gas supply pipe 292d at at least a downstream side of the valve 295d. A downstream end of a second gas supply pipe 292e is connected to the first gas supply pipe 292d at a downstream side of the valve 295d. A source gas supply source 298e, an MFC 299e which is a flow rate controller (flow rate control unit) and a valve 295e which is an opening/closing valve are sequentially installed at the second gas supply pipe 292e from an upstream end. A sub-heater 291e installed at the second gas supply pipe 292e at at least a downstream side of the valve 295e.

An operation of generating a process gas (a vaporized gas) by vaporizing a liquid source will be described below. First, a transfer gas is supplied into the liquid source supply tank 293 through the transfer gas supply pipe 292b via the MFC 299b and the valve 295b. Thus, a liquid source stored in the liquid source supply tank 293 is transferred into the liquid source supply pipe 289a. The liquid source supplied from the liquid source supply tank 293 into the liquid source supply pipe 289a is supplied into the reaction tube 203 via the liquid flow rate controller 294, the valve 295a, the separator 296, the valve 297 and the liquid source supply nozzle 501. When the liquid source supplied into the reaction tube 203 is in contact with the ceiling plate 217c heated by the third heating unit 209, the liquid source is vaporized to produce a process gas (vaporized gas). The process gas is supplied to the wafer 200 in the reaction tube 203 to perform predetermined substrate processing on the wafer 200.

In order to promote the vaporization of the liquid source, the liquid source flowing in the liquid source supply pipe 289a may be pre-heated by the sub-heater 291a. Thus, the liquid source that is in a more easily vaporizable state may be supplied into the reaction tube 203.

A liquid source supply system mainly includes the liquid source supply pipe 289a, the liquid flow rate controller 294, the valve 295a, the separator 296, the valve 297 and the liquid source supply nozzle 501. The liquid source supply tank 293, the transfer gas supply pipe 292b, the inert gas source 298b, the MFC 299b or the valve 295b may be further included in the liquid source supply system. A gas supply system is mainly configured by the liquid source supply system, the third heating unit 209 and the ceiling plate 217c.

An inert gas supply system mainly includes the inert gas supply pipe 292c, the MFC 299c and the valve 295c. The inert gas source 298c, the liquid source supply pipe 289a, the separator 296, the valve 297 or the liquid source supply nozzle 501 may be further included in the inert gas supply system. A first process gas supply system mainly includes the first gas supply pipe 292d, the MFC 299d and the valve 295d. The source gas supply source 298d, the liquid source supply pipe 289a, the liquid source supply nozzle 501, the third heating unit 209 or the ceiling plate 217c may be further included in the first process gas supply system. A second process gas supply system mainly includes the second gas supply pipe 292e, the MFC 299e and the valve 295e. The source gas supply source 298e, the liquid source supply pipe 292a, the first gas supply pipe 292b, the liquid source supply nozzle 501, the third heating unit 209 or the ceiling plate 217c may be further included in the second process gas supply system. Although the case in which the ceiling plate 217c is installed on the boat 217 has been described above, the ceiling plate 217c may be installed above the reaction tube 203 rather than on the boat 217.

The other elements of the substrate processing apparatus are substantially the same as those of the substrate processing apparatus according to the second or first embodiment and thus are not described again here.

### (2) Substrate Processing Process

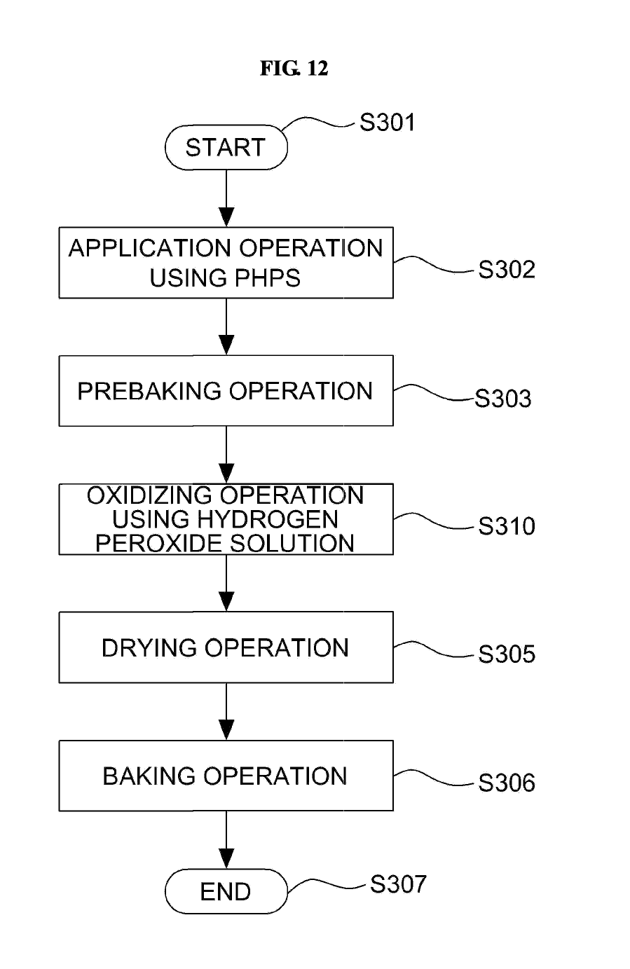

Next, a substrate processing process performed as a process included in a process of manufacturing a semiconductor device according to the present embodiment will be described with reference to FIG. 12 below. Operations of the substrate processing process except for an oxidizing process using a hydrogen peroxide solution (operation S310) are substantially the same as those of the second or first embodiment and thus are not described again here.

[Oxidizing Process using Hydrogen Peroxide Solution (Operation S310)]

When the wafer 200 is heated to a desired temperature and the speed of rotating the boat 217 reaches a desired speed, supply of a hydrogen peroxide solution which is a liquid source into the reaction tube 203 from the liquid source supply pipe 289a is started. That is, the valves 295c, 295d and 295e are closed, the valve 295b is opened, and a transfer gas is supplied from the transfer gas supply source 298b into the liquid source supply tank 293 while the flow rate of the transfer gas is controlled by the MFC 299b. Also, the valves 295a and 297 are opened, and a hydrogen peroxide solution stored in the liquid source supply tank 293 is supplied into the reaction tube 203 from the liquid source supply pipe 289a via the separator 296 and the liquid source supply nozzle 501 while the flow rate of the hydrogen peroxide solution is controlled by the liquid flow rate controller 294. As the transfer gas, an inert gas such as nitrogen (N2) gas or a noble gas such as He gas, Ne gas, Ar gas, etc. may be used.

A vaporized gas of the hydrogen peroxide solution supplied into the reaction tube 203 is produced as a process gas by vaporizing the hydrogen peroxide solution by bringing the hydrogen peroxide solution in contact with the ceiling plate 217c of the boat 217 heated by the third heating unit 209. As described above, the vaporized gas of the hydrogen peroxide solution which is a process gas may be produced in the reaction tube 203. That is, the hydrogen peroxide solution which is a liquid source may pass through the inside of the liquid source supply nozzle 501. The third heating unit 209 is set beforehand to heat the ceiling plate 217c to a temperature at which the hydrogen peroxide solution may be vaporized (e.g., 150° C. to 170° C.).

A silicon-containing film formed on the wafer 200 is modified into a SiO film by supplying the vaporized gas of the hydrogen peroxide solution to the wafer 200 and causing an oxidation reaction of the vaporized gas of the hydrogen peroxide solution with a surface of the wafer 200.

The hydrogen peroxide solution is exhausted from the vacuum pump 246b and the liquid collecting tank 247 while the hydrogen peroxide solution is supplied into the reaction tube 203. That is, the APC valve 255 is closed, the valve 240 is opened, and an exhaust gas exhausted from the inside of the reaction tube 203 is caused to pass through the separator 244 from the gas exhaust pipe 231 via the second exhaust pipe 243. Then, the exhaust gas is divided into a liquid that contains hydrogen peroxide and a gas that does not contain hydrogen peroxide by the separator 244, the gas is exhausted from the vacuum pump 246b, and the liquid is collected into the liquid collecting tank 247.

When the hydrogen peroxide solution is supplied into the reaction tube 203, the valve 240 and the APC valve 255 may be closed and pressure may be applied to the inside of the reaction tube 203. Thus, an atmosphere of the hydrogen peroxide solution in the reaction tube 203 may be uniformly controlled.

After a predetermined time elapses, the valves 295a, 295b and 297 are closed to stop the supply of the hydrogen peroxide solution into the reaction tube 203.

The present invention is not limited to using the vaporized gas of the hydrogen peroxide solution as a process gas, and for example, water vapor (H₂O) obtained by heating a gas containing the element hydrogen (H) (hydrogen-containing gas), e.g., hydrogen (H₂) gas, and a gas containing the element oxygen (O) (oxygen-radical-containing gas), e.g., oxygen (O₂) gas, may be used. That is, the valves 295a, 295b and 297 may be closed, the valves 295d and 295e may be opened, and H₂ gas and O₂ gas may be respectively supplied into the reaction tube 203 from the first gas supply pipe 292d and the second gas supply pipe 292e while the flow rates of the H₂ gas and the O₂ gas are controlled by the MFCs 299d and 299e. Also, water vapor may be generated by bringing the H₂ gas and the O₂ gas supplied into the reaction tube 203 in contact with the ceiling plate 217c of the boat 217 heated by the third heating unit 209, and supplied to the wafer 200 to modify a silicon-containing film formed on the wafer 200 into a SiO film. As the oxygen-containing gas, for example, ozone (O₃) gas, water vapor (H₂O), etc. may be used in addition to O₂ gas.

### (3) Effects of the Third Embodiment

According to the third embodiment, not only the effects of the first and second embodiments but also one or more of the following effects may be derived.

(a) Since a source liquid is vaporized in the process chamber 201, dew condensation does not occur in the gas supply unit, thereby decreasing foreign substances generated on the wafer 200.

(b) Since the distance between a gas generation source and the exhaust unit is decreased, a gas is prevented from being liquefied in the exhaust unit. Also, foreign substances generated on the wafer 200 due to backflow of a gas that is reliquefied and revaporized in the exhaust unit may be decreased.

Although the third embodiment has been described above in detail, the third embodiment is not limited to that described above and may be embodied in many different forms without departing from the scope of the invention

Also, in the above case in which a hydrogen peroxide solution (H₂O₂) is used as a vaporizing source, an example of a gas to be supplied to the wafer 200 may include a state of H₂O₂ molecules or a cluster state in which various molecules are bound to each other. Also, when a gas is generated from a liquid, the gas may be divided until H₂O₂ molecules or a cluster state in which various molecules are bound to each other is obtained. Also, a gas to be supplied to the wafer 200 may have a mist state produced when a plurality of such clusters are gathered together.

Although a process of filling a fine groove with an insulator has been described above as a process of manufacturing a semiconductor device for processing the wafer 200, the invention according to the first to third embodiments is applicable to other processes. For example, the invention is applicable to a process of forming an interlayer insulating film of a semiconductor device substrate, a process of encapsulating a semiconductor device, etc.

Also, although a process of manufacturing a semiconductor device has been described above, the invention according to the first to third embodiments is applicable to other processes. For example, the invention is applicable to encapsulating a substrate containing liquid crystal in a process of manufacturing a liquid crystal device, or a water-repellent coating on a glass substrate or a ceramic substrate for use in various devices. Also, the present invention is applicable to a water-repellent coating on a mirror, or the like.

Also, although the case in which a process gas is generated by heating and vaporizing water vapor (H₂O) produced from oxygen gas and hydrogen gas, water (H₂O) as an oxidizer solution, or a hydrogen peroxide solution (H₂O₂) has been described above, the present invention is not limited thereto, and water (H₂O) or a hydrogen peroxide solution (H₂O₂) may be changed into a mist form by adding ultrasound waves thereto or mist may be sprayed using an atomizer. Otherwise, a solution may be vaporized by directly radiating a laser or microwaves onto the solution in a moment.

Also, although the case in which hydrogen peroxide is supplied to a substrate on which a film containing PHPS is formed to form a silicon oxide film has been described above, the present invention is not limited thereto, and a silicon oxide film may be formed by vapor growth. For example, a silicon film or a silicon oxide film may be formed by vapor growth using at least one material selected from the group consisting of hexa-methyl-disilazane (HMDS), (HMCTS), polycarbosilazane, polyorganosilazane, and trisilylamine (TSA).

Also, although the application operation using PHPS (operation S302) to the baking operation (operation S306) are performed in the previous embodiments, the present invention is not limited thereto, and a substrate on which the application operation using PHPS (operation S302) to the prebaking operation (operation S303) are performed may be accommodated in a process chamber, and the oxidizing operation using a hydrogen peroxide solution (operation S304) and the baking operation (operation S306) may be performed. Alternatively, the oxidizing operation using a hydrogen peroxide solution (operation S304) and the baking operation (operation S306) may be performed in different process chambers.

With a method of manufacturing a semiconductor device, a substrate processing apparatus and a non-transitory computer-readable recording medium according to the present invention, the manufacturing throughput of a semiconductor device can be increased while improving the manufacturing quality thereof.

### Preferred Embodiments of the Present Invention

Hereinafter, preferred embodiments according to the present invention are supplementarily noted.

### Supplementary Note 1

According to an aspect of the present invention, there is provided a method of manufacturing a semiconductor device including: (a) accommodating a substrate having thereon a film containing a silazane bond in a process chamber; (b) generating a process gas by supplying a process liquid containing hydrogen peroxide to an evaporator and supplying the process gas to the substrate; and (c) supplying a microwave to the substrate after processing the substrate with the process gas.

### Supplementary Note 2

In the method of Supplementary note 1, preferably, a plurality of fine concavo-convex structures are formed on the substrate, and concavities of the plurality of fine concavo-convex structure are filled with the film containing the silazane bond.

### Supplementary Note 3

In the method of Supplementary note 2, preferably, the concavities are formed using at least one of a gate insulating film and a gate electrode.

### Supplementary Note 4

In the method of Supplementary note 1, preferably, the evaporator is installed in the process chamber and the process gas is generated within the process chamber.

### Supplementary Note 5

In the method of Supplementary note 1, preferably, further including prebaking the film containing the silazane bond to cure the film before performing the step (b).

### Supplementary Note 6

In the method of Supplementary note 2, preferably, the plurality of fine concavo-convex structures are trenches included in the semiconductor device.

### Supplementary Note 7

In the method of Supplementary note 1, preferably, the film containing the silazane bond is a polysilazane film.

### Supplementary Note 8

In the method of Supplementary note 1, preferably, further including supplying the microwave to the substrate when the step (b) is performed.

### Supplementary Note 9

In the method of Supplementary note 1, preferably, the step (c) is performed while varying a frequency of the microwave.

### Supplementary Note 10

In the method of Supplementary note 1, preferably, the steps (b) and (c) are performed in the same housing in which a plurality of process chambers are installed.

### Supplementary Note 11

In the method of Supplementary note 1, preferably, after the step (b), the substrate is transferred to a separate process chamber and then the step (c) is performed.

### Supplementary Note 12

According to another aspect of the present invention, there is provided a substrate processing apparatus including: a process chamber configured to accommodate a substrate having thereon a film containing a silazane bond; an evaporation device including an evaporator configured to receive a process liquid containing hydrogen peroxide; a microwave supply unit configured to supply a microwave to the substrate; and a control unit configured to control the evaporation device and the microwave supply unit to generate a process gas from the process liquid supplied to the evaporator and supply the microwave to the substrate after the process gas is supplied to the substrate.

### Supplementary Note 13

In the substrate processing apparatus of Supplementary note 12, preferably, a plurality of fine concavo-convex structures are formed on the substrate, and concavities of the plurality of fine concavo-convex structure are filled with the film containing the silazane bond.

### Supplementary Note 14

In the substrate processing apparatus of Supplementary note 13, preferably, the concavities are formed using at least one of a gate insulating film and a gate electrode.

### Supplementary Note 15

In the substrate processing apparatus of Supplementary note 12, preferably, the evaporator is installed in the process chamber, and the control unit is configured to control the evaporation device to generate the process gas within the process chamber.

### Supplementary Note 16

In the substrate processing apparatus of Supplementary note 12, preferably, the control unit is further configured to control the microwave supply unit to supply the microwave to the substrate while varying a frequency of the microwave.

### Supplementary Note 17

In the substrate processing apparatus of Supplementary note 12, preferably, the microwave supply unit is configured to supply the microwave in horizontal direction to the substrate.

### Supplementary Note 18

According to still another aspect of the present invention, there is provided a program for causing a computer to control a substrate processing apparatus to perform: (a) accommodating a substrate having thereon a film containing a silazane bond in a process chamber; (b) generating a process gas by supplying a process liquid containing hydrogen peroxide to an evaporator and supplying the process gas to the substrate; and (c) supplying a microwave to the substrate after processing the substrate with the process gas.

### Supplementary Note 19

In the program of Supplementary note 18, preferably, a plurality of fine concavo-convex structures are formed on the substrate, and concavities of the plurality of fine concavo-convex structure are filled with the film containing the silazane bond.

### Supplementary Note 20

In the program of Supplementary note 19, preferably, the concavities are formed using at least one of a gate insulating film and a gate electrode.

### Supplementary Note 21

In the program of Supplementary note 19, preferably, the evaporator is installed in the process chamber, and the process gas is generated within the process chamber.

### Supplementary Note 22

In the program of Supplementary note 19, preferably, further including prebaking the film containing the silazane bond to cure the film before performing the sequence (b).

### Supplementary Note 23

In the program of Supplementary note 19, preferably, the plurality of fine concavo-convex structures are trenches of the semiconductor device.

### Supplementary Note 24

In the program of Supplementary note 19, preferably, further including supplying the microwave to the substrate when the sequence (b) is performed.

### Supplementary Note 25

In the program of Supplementary note 19, preferably, the sequence (c) is performed while varying a frequency of the microwave.

### Supplementary Note 26

According to another aspect of the present invention, there is provided a non-transitory computer-readable recording medium storing a program for causing a computer to control a substrate processing apparatus to perform: (a) accommodating a substrate having thereon a film containing a silazane bond in a process chamber; (b) generating a process gas by supplying a process liquid containing hydrogen peroxide to an evaporator and supplying the process gas to the substrate; and (c) supplying a microwave to the substrate after processing the substrate with the process gas.

What is claimed is:

1. A method of manufacturing a semiconductor device comprising:
(a) accommodating a substrate having thereon a film containing a silazane bond in a process chamber;
(b) generating a process gas by supplying a process liquid containing hydrogen peroxide to an evaporator and supplying the process gas to the substrate; and
(c) supplying a microwave to the substrate after processing the substrate with the process gas.

2. The method of claim 1, wherein the evaporator is installed in the process chamber and the process gas is generated within the process chamber.

3. The method of claim 1, wherein the process liquid is dripped onto the evaporator to generate the process gas.

4. The method of claim 2, wherein the process liquid is dripped onto the evaporator to generate the process gas.

5. The method of claim 1, further comprising prebaking the film containing the silazane bond to cure the film before performing the step (b).

6. The method of claim 1, further comprising supplying the microwave to the substrate when the step (b) is performed.

7. The method of claim 1, wherein the step (c) is performed while varying a frequency of the microwave.

8. A substrate processing apparatus comprising:
a process chamber configured to accommodate a substrate having thereon a film containing a silazane bond;
an evaporation device comprising an evaporator configured to receive a process liquid containing hydrogen peroxide;
a microwave supply unit configured to supply a microwave to the substrate; and
a control unit configured to control the evaporation device and the microwave supply unit to generate a process gas from the process liquid supplied to the evaporator and supply the microwave to the substrate after the process gas is supplied to the substrate.

9. The substrate processing apparatus of claim 8, wherein the evaporator is installed in the process chamber.

10. The substrate processing apparatus of claim 8, wherein the process liquid is dripped onto the evaporator to generate the process gas.

11. The substrate processing apparatus of claim 8, wherein the control unit is further configured to control the microwave supply unit to supply the microwave to the substrate while varying a frequency of the microwave.

12. The substrate processing apparatus of claim 8, wherein the microwave supply unit is configured to supply the microwave in direction parallel to the substrate.

13. A non-transitory computer-readable recording medium storing a program for causing a computer to control a substrate processing apparatus to perform:
(a) accommodating a substrate having thereon a film containing a silazane bond in a process chamber;
(b) generating a process gas by supplying a process liquid containing hydrogen peroxide to an evaporator and supplying the process gas to the substrate; and
(c) supplying a microwave to the substrate after processing the substrate with the process gas.

14. The non-transitory computer-readable recording medium of claim 13, wherein the evaporator is installed in the process chamber, and the process gas is generated within the process chamber.

15. The non-transitory computer-readable recording medium of claim 13, further comprising prebaking the film containing the silazane bond to cure the film before performing the sequence (b).

16. The non-transitory computer-readable recording medium of claim 13, further comprising supplying the microwave to the substrate when the sequence (b) is performed.

17. The non-transitory computer-readable recording medium of claim 13, wherein the sequence (c) is performed while varying a frequency of the microwave.
